(19) United States
(12) Patent Application Publication
(10) Pub. No.: US 2025/0359269 A1
(43) Pub. Date: Nov. 20, 2025

(54) NITRIDE-BASED SEMICONDUCTOR DEVICE AND METHOD FOR MANUFACTURING THE SAME

(71) Applicant: INNOSCIENCE (SUZHOU) SEMICONDUCTOR CO., LTD., Suzhou, Jiangsu (CN)

(72) Inventors: Xiaoyan ZHANG, Suzhou, Jiangsu (CN); Jinhan ZHANG, Suzhou, Jiangsu (CN); King Yuen WONG, Suzhou, Jiangsu (CN)

(73) Assignee: INNOSCIENCE (SUZHOU) SEMICONDUCTOR CO., LTD., Suzhou, Jiangsu (CN)

(21) Appl. No.: 19/106,322

(22) PCT Filed: Aug. 31, 2022
(86) PCT No.: PCT/CN2022/116103

§ 371 Date: Feb. 25, 2025

(51) Int. Cl. H10D 64/27; H10D 30/01; H10D 30/47; H10D 62/85

(52) U.S. Cl. CPC H10D 64/411; H10D 30/015; H10D 30/475; H10D 62/8503

(57) ABSTRACT

A nitride-based semiconductor device includes a first nitride-based semiconductor layer, a second nitride-based semiconductor layer, a first conductive layer, a second conductive layer, and a gate electrode. The second nitride-based semiconductor layer is disposed over the first nitride-based semiconductor layer and has a bandgap greater than a bandgap of the first nitride-based semiconductor layer. The first conductive layer is disposed over the second nitride-based semiconductor layer and has a top surface and a plurality of recesses at the top surface. The second conductive layer at least fills into the recesses, in which the first conductive layer includes at least one first element excluded in the second conductive layer. The gate electrode is disposed over the first conductive layer and the second conductive layer.

### CROSS-REFERENCE TO RELATED APPLICATIONS

This application is a national stage of international PCT Application No. PCT/CN2022/116103 filed on Aug. 31, 2022, the entire contents of which are incorporated herein by reference.

### FIELD OF THE DISCLOSURE

The present disclosure generally relates to a nitride-based semiconductor device. More specifically, the present disclosure relates to a nitride-based semiconductor device including a gate electrode coated by an aluminum layer.

### BACKGROUND OF THE DISCLOSURE

In recent years, intense research on high-electron-mobility transistors (HEMTs) has been prevalent, particularly for high power switching and high frequency applications. III-nitride-based HEMTs utilize a heterojunction interface between two materials with different bandgaps to form a quantum well-like structure, which accommodates a two-dimensional electron gas (2DEG) region, satisfying demands of high power/frequency devices. In addition to HEMTs, examples of devices having heterostructures further include heterojunction bipolar transistors (HBT), heterojunction field effect transistor (HFET), and modulation-doped FETs (MODFET).

### SUMMARY OF THE DISCLOSURE

In accordance with one aspect of the present disclosure, a nitride-based semiconductor device is provided. The nitride-based semiconductor device includes a first nitride-based semiconductor layer, a second nitride-based semiconductor layer, a first conductive layer, a second conductive layer, and a gate electrode. The second nitride-based semiconductor layer is disposed over the first nitride-based semiconductor layer and has a bandgap greater than a bandgap of the first nitride-based semiconductor layer. The first conductive layer is disposed over the second nitride-based semiconductor layer and has a top surface and a plurality of recesses at the top surface. The second conductive layer at least fills into the recesses, in which the first conductive layer comprises at least one first element excluded in the second conductive layer. The gate electrode is disposed over the first conductive layer and the second conductive layer.

In accordance with one aspect of the present disclosure, a method for manufacturing a nitride-based semiconductor device is provided. The method has steps as follows: forming a first nitride-based semiconductor layer; forming a second nitride-based semiconductor layer on the first nitride-based semiconductor layer; forming a first conductive layer over the second nitride-based semiconductor layer; forming a second conductive layer to fill recesses of the first conductive layer; and forming a gate electrode over the first and second conductive layer.

In accordance with one aspect of the present disclosure, a nitride-based semiconductor device is provided. The nitride-based semiconductor device includes a first nitride-based semiconductor layer, a second nitride-based semiconductor layer, a first conductive layer, and a second conductive layer. The second nitride-based semiconductor layer is disposed over the first nitride-based semiconductor layer and has a bandgap greater than a bandgap of the first nitride-based semiconductor layer. The first conductive layer is disposed over the second nitride-based semiconductor layer and has a top surface and a plurality of recesses at the top surface. The second conductive layer at least fills into the recesses, in which the second conductive layer comprises aluminum which diffuses into the first conductive layer.

By the above configuration, element of aluminum in the second conductive layer may diffuse into the first conductive layer at the formation stage of the second conductive layer. As such, the contact resistance between the first and second conductive layers can get reduced, thereby increasing of stability with respect to threshold voltage of the nitride-based semiconductor device.

### BRIEF DESCRIPTION OF THE DRAWINGS

Aspects of the present disclosure are readily understood from the following detailed description when read with the accompanying figures. It should be noted that various features may not be drawn to scale. That is, the dimensions of the various features may be arbitrarily increased or reduced for clarity of discussion. Embodiments of the present disclosure are described in more detail hereinafter with reference to the drawings, in which:

FIG. 1 is a vertical cross-sectional view of a nitride-based semiconductor device according to some embodiments of the present disclosure;

FIG. 2A, FIG. 2B, FIG. 2C, and FIG. 2D show different stages of a method for manufacturing a nitride-based semiconductor device according to some embodiments of the present disclosure;

FIG. 3 is a vertical cross-sectional view of a nitride-based semiconductor device according to some embodiments of the present disclosure;

FIG. 4 is a vertical cross-sectional view of a nitride-based semiconductor device according to some embodiments of the present disclosure; and

FIG. 5 is a vertical cross-sectional view of a nitride-based semiconductor device according to some embodiments of the present disclosure.

### DETAILED DESCRIPTION

Common reference numerals are used throughout the drawings and the detailed description to indicate the same or similar components. Embodiments of the present disclosure will be readily understood from the following detailed description taken in conjunction with the accompanying drawings.

Spatial descriptions, such as “on,” “above,” “below,” “up,” “left,” “right,” “down,” “top,” “bottom,” “vertical,” “horizontal,” “side,” “higher,” “lower,” “upper,” “over,” “under,” and so forth, are specified with respect to a certain component or group of components, or a certain plane of a component or group of components, for the orientation of the component(s) as shown in the associated figure. It should be understood that the spatial descriptions used herein are for purposes of illustration only, and that practical implementations of the structures described herein can be spatially arranged in any orientation or manner, provided that the merits of embodiments of this disclosure are not deviated from by such arrangement.

Further, it is noted that the actual shapes of the various structures depicted as approximately rectangular may, in actual device, be curved, have rounded edges, have somewhat uneven thicknesses, etc. due to device fabrication conditions. The straight lines and right angles are used solely for convenience of representation of layers and features.

In the following description, semiconductor devices/dies/packages, methods for manufacturing the same, and the likes are set forth as preferred examples. It will be apparent to those skilled in the art that modifications, including additions and/or substitutions may be made without departing from the scope and spirit of the present disclosure. Specific details may be omitted so as not to obscure the present disclosure; however, the disclosure is written to enable one skilled in the art to practice the teachings herein without undue experimentation.

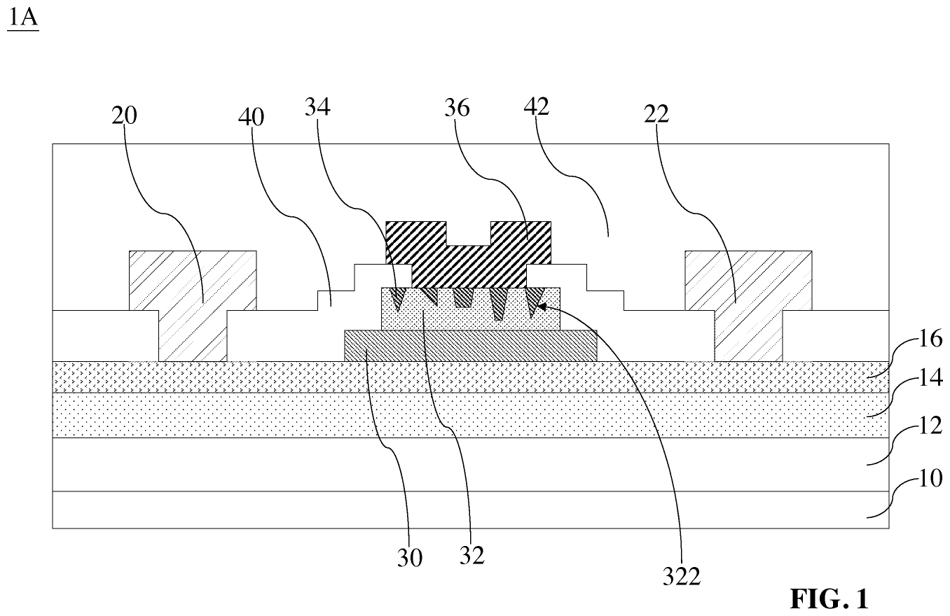

FIG. 1 is a vertical cross-sectional view of a nitride-based semiconductor device 1A according to some embodiments of the present disclosure. The nitride-based semiconductor device 1A includes a substrate 10, a buffer layer 12, nitride-based semiconductor layers 14, 16, electrodes 20 and 22, a doped nitride-based semiconductor layer 30, conductive layers 32 and 34, a gate electrode 36, and passivation layers 40 and 42.

The substrate 10 may be a semiconductor substrate. The exemplary materials of the substrate 10 can include, for example but are not limited to, Si, SiGe, SiC, gallium arsenide, p-doped Si, n-doped Si, sapphire, semiconductor on insulator, such as silicon on insulator (SOI), or other suitable substrate materials. In some embodiments, the substrate 10 can include, for example, but is not limited to, group III elements, group IV elements, group V elements, or combinations thereof (e.g., III-V compounds). In other embodiments, the substrate 10 can include, for example but is not limited to, one or more other features, such as a doped region, a buried layer, an epitaxial (epi) layer, or combinations thereof.

The buffer layer 12 is disposed between the substrate 10 and the nitride-based semiconductor layer 14. The buffer layer 12 can be configured to reduce lattice and thermal mismatches between the substrate 10 and the nitride-based semiconductor layer 14, thereby curing defects due to the mismatches/difference. The buffer layer 12 may include a III-V compound. The III-V compound can include, for example but are not limited to, aluminum, gallium, indium, nitrogen, or combinations thereof. Accordingly, the exemplary materials of the buffer layer 12 can further include, for example but are not limited to, GaN, AlN, AlGaN, InAlGaN, or combinations thereof.

In some embodiments, the semiconductor device 1A may further include a nucleation layer (not shown). The nucleation layer may be formed between the substrate 10 and the buffer layer 12. The nucleation layer can be configured to provide a transition to accommodate a mismatch/difference between the substrate 10 and a III-nitride layer of the buffer layer 12. The exemplary material of the nucleation layer can include, for example but is not limited to AlN or any of its alloys.

The nitride-based semiconductor layer 14 can be disposed on/over/above the buffer layer 12. The nitride-based semiconductor layer 16 can be disposed on/over/above the nitride-based semiconductor layer 14. The exemplary materials of the nitride-based semiconductor layer 14 can include, for example but are not limited to, nitrides or group III-V compounds, such as GaN, AlN, InN, InₓAl_{y}Ga_{(1-x-y)}N where x+y≤1, AlₓGa₍₁₋ₓ₎N where x≤1. The exemplary materials of the nitride-based semiconductor layer 16 can include, for example but are not limited to, nitrides or group III-V compounds, such as GaN, AlN, InN, InₓAl_{y}Ga_{(1-x-y)}N where x+y≤1, Al_{y}Gan_{(1-y)}N where y≤1.

The exemplary materials of the nitride-based semiconductor layers 14 and 16 are selected such that the nitride-based semiconductor layer 16 has a bandgap (i.e., forbidden band width) greater/higher than a bandgap of the nitride-based semiconductor layer 14, which causes electron affinities thereof different from each other and forms a heterojunction therebetween. For example, when the nitride-based semiconductor layer 14 is an undoped GaN layer having a bandgap of approximately 3.4 eV, the nitride-based semiconductor layer 16 can be selected as an AlGaN layer having bandgap of approximately 4.0 eV. As such, the nitride-based semiconductor layers 14 and 16 can serve as a channel layer and a barrier layer, respectively. A triangular well potential is generated at a bonded interface between the channel and barrier layers, so that electrons accumulate in the triangular well, thereby generating a two-dimensional electron gas (2DEG) region adjacent to the heterojunction. Accordingly, the semiconductor device IA is available to include at least one GaN-based high-electron-mobility transistor (HEMT).

The electrodes 20 and 22 are disposed on the nitride-based semiconductor layer 16. The electrode 20 can make contact with the nitride-based semiconductor layer 16. The electrode 22 can make contact with the nitride-based semiconductor layer 16. Each of the electrodes 20 and 22 can serve as a source electrode or a drain electrode.

In some embodiments, the electrodes 20 and 22 can include, for example but are not limited to, metals, alloys, doped semiconductor materials (such as doped crystalline silicon), compounds such as silicides and nitrides, other conductor materials, or combinations thereof. The exemplary materials of the electrodes 20 and 22 can include, for example but are not limited to, Ti, AlSi, TiN, or combinations thereof. The electrodes 20 and 22 may be a single layer, or plural layers of the same or different composition. In some embodiments, the electrodes 20 and 22 form ohmic contact with the nitride-based semiconductor layer 16. The ohmic contact can be achieved by applying Ti, Al, or other suitable materials to the electrodes 20 and 22.

In some embodiments, each of the electrodes 20 and 22 is formed by at least one conformal layer and a conductive filling. The conformal layer can wrap the conductive filling. The exemplary materials of the conformal layer can include, for example but are not limited to, Ti, Ta, TiN, Al, Au, AlSi, Ni, Pt, or combinations thereof. The exemplary materials of the conductive filling can include, for example but are not limited to, AlSi, AlCu, or combinations thereof.

The doped nitride-based semiconductor layer 30 is disposed over the nitride-based semiconductor layer 16. The doped nitride-based semiconductor layer 30 is located between the electrodes 20 and 22. The doped nitride-based semiconductor layer 30 may be p-type. The doped nitride-based semiconductor layer 30 is configured to bring the device into enhancement mode. The doped nitride-based semiconductor layer 30 can be a p-type doped III-V semiconductor layer.

The exemplary materials of the doped nitride-based semiconductor layer 30 can include, for example but are not limited to, p-doped group III-V nitride semiconductor materials, such as p-type GaN, p-type AlGaN, p-type InN, p-type AlInN, p-type InGaN, p-type AlInGaN, or combinations thereof. In some embodiments, the p-doped materials are achieved by using a p-type impurity, such as Be, Mg, Zn, Cd, and Mg.

The conductive layer 32 is disposed over the nitride-based semiconductor layer 16 and the doped nitride-based semiconductor layer 30. The doped nitride-based semiconductor layer 30 is located between the nitride-based semiconductor layer 16 and the conductive layer 32. The doped nitride-based semiconductor layer 30 is wider than the conductive layer 32.

The conductive layer 32 has a top surface facing away the doped nitride-based semiconductor layer 30. The conductive layer 32 may have a plurality of recesses 322 at the top surface. The conductive layer 32 may have a columnar crystal structure rather than a dense structure. Accordingly, the recesses 322 may be created during the formation of the conductive layer 32, such as a deposition process. The process condition may affect the profile of the recesses 322. In some embodiments, the recesses 322 of the conductive layer 32 may have different depths.

The exemplary materials of the conductive layer 32 may include metals or metal compounds. The exemplary materials of the metals or metal compounds can include, for example but are not limited to, TiN, TaN, or combinations thereof.

Recesses at a layer may result in unexpected bad affection. For example, yield rate or reliability may reduce. On the other hand, an uneven contact surface may make resistance between the surface and a layer to be formed thereon increase. To address such the issue, the present disclosure is to provide a coating covering the recesses 322 of the conductive layer 32.

The conductive layer 34 is disposed over the conductive layer 32. The conductive layer 34 can fill into the recesses 322 of the conductive layer 32. The conductive layer 34 can serve as a coating layer with respect to the conductive layer 32. The conductive layer 34 can fill up the recesses 322 of the conductive layer 32. In some embodiments, the conductive layer 34 is exactly within a thickness of the conductive layer 32, which means top surfaces of the conductive layers 32 and 34 are coplanar with each other, so as to create a flat surface.

The conductive layers 32 and 34 may have different materials. For example, the conductive layer 32 includes metal or element excluded in the conductive layer 34. The conductive layer 34 includes a group III element different than the metal or the element contained in the conductive layer 32. For example, the conductive layer 32 includes titanium and the conductive layer 34 includes aluminum. In some embodiments, the conductive layers 32 can serve as a gate first layer and is made of TiN (e.g. a titanium nitrate layer), and the conductive layer 34 is a layer of Al (e.g. an aluminum layer).

Furthermore, after the formation of the conductive layer 34, an annealing process is applied to the conductive layer 34. During the annealing process, element of aluminum may diffuse into the conductive layer 32 from the conductive layer 34. As such, the contact resistance between the conductive layers 32 and 34 can get reduced, thereby increasing of stability with respect to threshold voltage Vth of the nitride-based semiconductor device IA.

The gate electrode 36 is disposed over the conductive layers 32 and 34. The gate electrode 36 can make contact with the conductive layer 32. The gate electrode 36 can make contact with the conductive layer 34. The gate electrode 36 can make contact with a flat top surface collectively constructed by the conductive layers 32 and 34. As the contact resistance between the conductive layers 32 and 34 is reduced, the contact resistance of the gate electrode 36 with respect to the conductive layers 32 and 34 reduces as well.

The exemplary materials of the gate electrode 36 may include metals or metal compounds. The gate electrode 36 may be formed as a single layer, or plural layers of the same or different compositions. The exemplary materials of the metals or metal compounds can include, for example but are not limited to, W, Au, Pd, Ti, Ta, Co, Ni, Pt, Mo, TiN, TaN, metal alloys or compounds thereof, or other metallic compounds.

The passivation layer 40 is disposed over the nitride-based semiconductor layer 16. The passivation layer 40 can cover the doped nitride-based semiconductor layer 30 and the conductive layers 32 and 34. The electrodes 20 and 22 can penetrate the passivation layer 40 to get contact with the nitride-based semiconductor layer 16. The gate electrode 36 can penetrate the passivation layer 40 to get contact with the conductive layers 32 and 34.

The passivation layer 40 can be made of dielectric so as to serve as a dielectric layer. The material of the passivation layer 40 can include, for example but are not limited to, dielectric materials. For example, the passivation layer 40 can include SiNₓ, SiOₓ, SiON, SiC, SiBN, SiCBN, oxides, nitrides, plasma enhanced oxide (PEOX), or combinations thereof.

The passivation layer 42 is disposed over the passivation layer 40. The passivation layer 42 can cover the electrodes 20 and 22 and the gate electrode 36. The electrodes 20 and 22 can penetrate the passivation layer 40 to get contact with the nitride-based semiconductor layer 16. The gate electrode 36 can penetrate the passivation layer 40 to get contact with the conductive layers 32 and 34. In some embodiments, the passivation layer 42 can serve as a planarization layer which has a level top surface to support other layers/elements. In some embodiments, the passivation layer 42 can be formed as a thicker layer, and a planarization process, such as chemical mechanical polish (CMP) process, is performed on the passivation layer 42 to remove the excess portions, thereby forming a level top surface.

The passivation layer 42 can be made of dielectric so as to serve as a dielectric layer. The material of the passivation layer 42 can include, for example but are not limited to, dielectric materials. For example, the passivation layer 42 can include SiNₓ, SiOₓ, SiON, SiC, SiBN, SiCBN, oxides, nitrides, plasma enhanced oxide (PEOX), or combinations thereof.

In some embodiments, the nitride-based semiconductor device 1A may further include at least one contact via and at least one patterned conductive layer. The contact via and the patterned conductive layer may be shown in other cross-sectional view. The contact via and the patterned conductive layer can be configured to electrically couple the electrodes 20 and 22 and the gate electrode 36 to an external circuit.

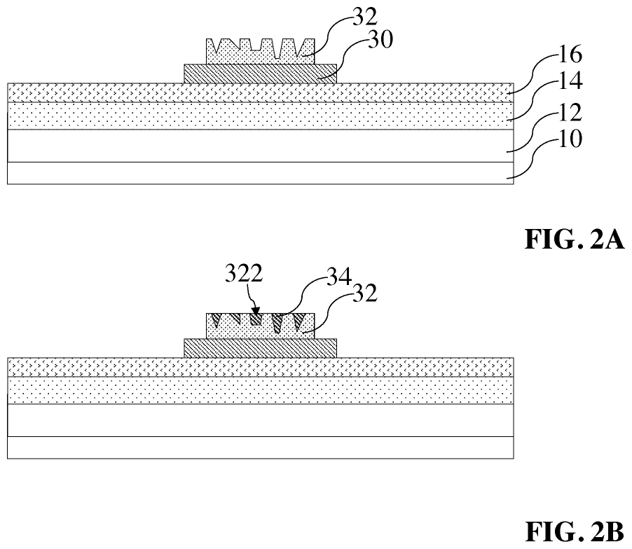

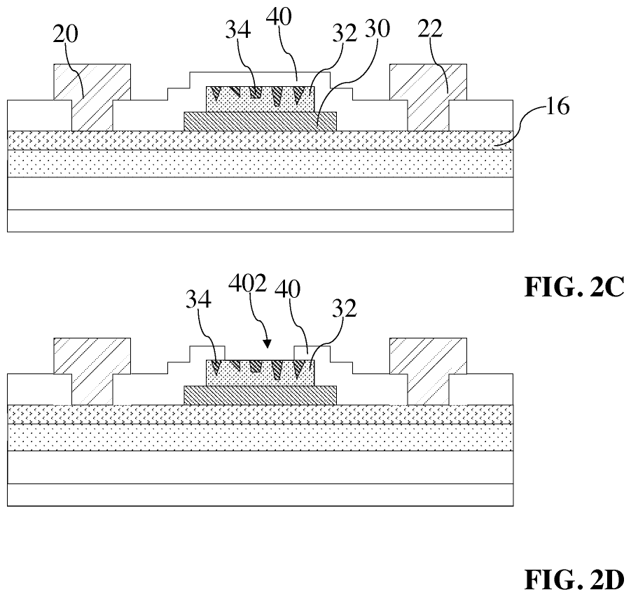

Different stages of a method for manufacturing the semiconductor device IA are shown in FIG. 2A, FIG. 2B, FIG. 2C, and FIG. 2D, described below. In the following, deposition techniques can include, for example but are not limited to, atomic layer deposition (ALD), physical vapor deposition (PVD), chemical vapor deposition (CVD), metal organic CVD (MOCVD), plasma enhanced CVD (PECVD), low-pressure CVD (LPCVD), plasma-assisted vapor deposition, epitaxial growth, or other suitable processes.

Referring to FIG. 2A, a substrate 10 is provided. A buffer layer 12 is formed on/over/above the substrate 10. A nitride-based semiconductor layer 14 is formed on the buffer layer 12. A nitride-based semiconductor layer 16 is formed on the nitride-based semiconductor layer 14. A doped nitride-based semiconductor layer 30 is formed on/over/above the nitride-based semiconductor layer 16. A conductive layer 32 is formed on/over/above the doped nitride-based semiconductor layer 30. After the formation of the conductive layer 32, a top surface of the conductive layer 32 can be cleaned by using a solution of hydrogen fluoride to remove oxygen. The conductive layer 32 is formed with recesses 322 located the top surface thereof.

Referring to FIG. 2B, a conductive layer 34 is formed to fill recesses 322 of the conductive layer 32. The conductive layer 34 can be formed by using deposition techniques. After forming the conductive layer 34, an annealing process is performed such that at least one group III element in the conductive layer 34 diffuses into the conductive layer 32. In some embodiments, the diffusing group III element is aluminum.

Referring to FIG. 2C, a passivation layer 40 is formed to cover the doped nitride-based semiconductor layer 30 and the conductive layers 32 and 34. Contact holes can be formed in the passivation layer 40. Thereafter, electrodes 20 and 22 can be formed over the nitride-based semiconductor layer 16. The electrodes 20 and 22 pass through contact holes to make contact with the nitride-based semiconductor layer 16.

Referring to FIG. 2D, an opening 402 is formed in the passivation 40 to expose the conductive layers 32 and 34. The opening 402 is configured to provide a contact window for a gate electrode. Thereafter, a gate electrode can be formed to make contact with the conductive layers 32 and 34. Then, a passivation layer, contact vias, and a patterned conductive layer are formed to obtaining the structure as afore above.

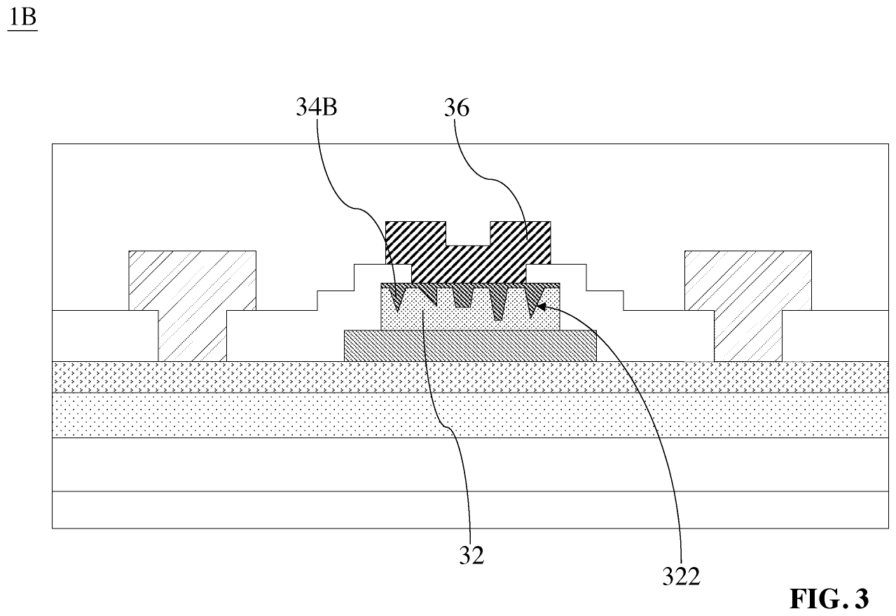

FIG. 3 is a vertical cross-sectional view of a nitride-based semiconductor device 1B according to some embodiments of the present disclosure. The nitride-based semiconductor device 1B is similar to the semiconductor device IA as described and illustrated with reference to FIG. 1, except that the conductive layer 34 of the semiconductor device IA is replaced by a conductive layer 34B. The recesses 322 of the conductive layer 32 are filled up by the conductive layer 34B. The conductive layer 34B can form a continuous layer on the conductive layer 32. Therefore, an entirety of the conductive layer 32 is separated from the gate electrode 36 by the conductive layer 34B. In the present embodiment, the diffusion of aluminum from the conductive layer 34B to the conductive layer 32 can get more uniform, because the top edge of the conductive layer 32 is entirely covered by the conductive layer 34B.

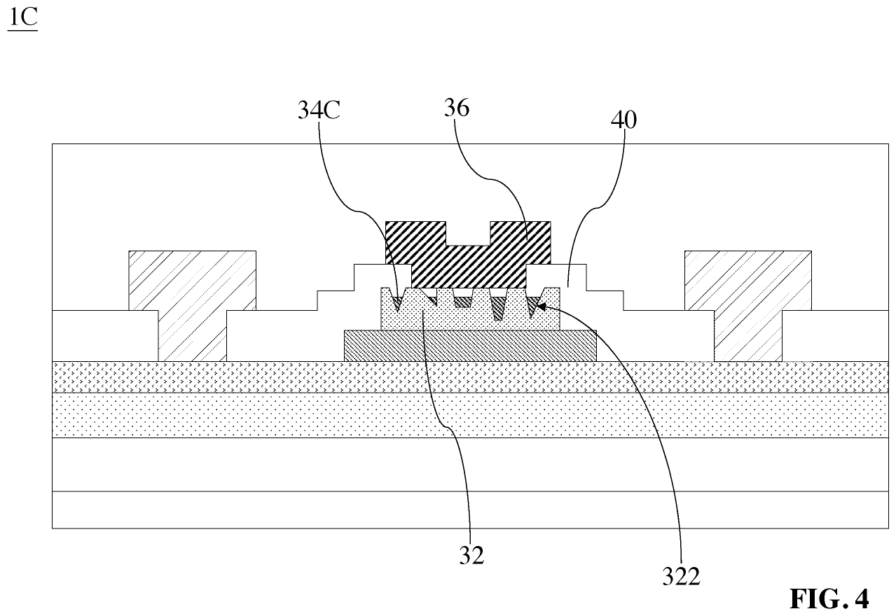

FIG. 4 is a vertical cross-sectional view of a nitride-based semiconductor device IC according to some embodiments of the present disclosure. The nitride-based semiconductor device 1C is similar to the semiconductor device IA as described and illustrated with reference to FIG. 1, except that the conductive layer 34 of the semiconductor device IA is replaced by a conductive layer 34C.

The recesses 322 of the conductive layer 32 are partially filled by the conductive layer 34C. An entirety of the conductive layer 34C is located within a thickness of the conductive layer 32. An entirety of the conductive layer 34C is at a position lower than a top surface of the conductive layer 32. The gate electrode 36 is free from contact with the conductive layer 34C. The gate electrode 36 can make contact with the conductive layer 32. The dielectric layer 40 can extend to the recesses 322 of the conductive layer 32 to fill up the recesses 322 of the conductive layer 32. In the present embodiment, the process for depositing the conductive layer 34C is in a short period and the profile of the formed conductive layer 34C is simple so the process stability can get controlled better.

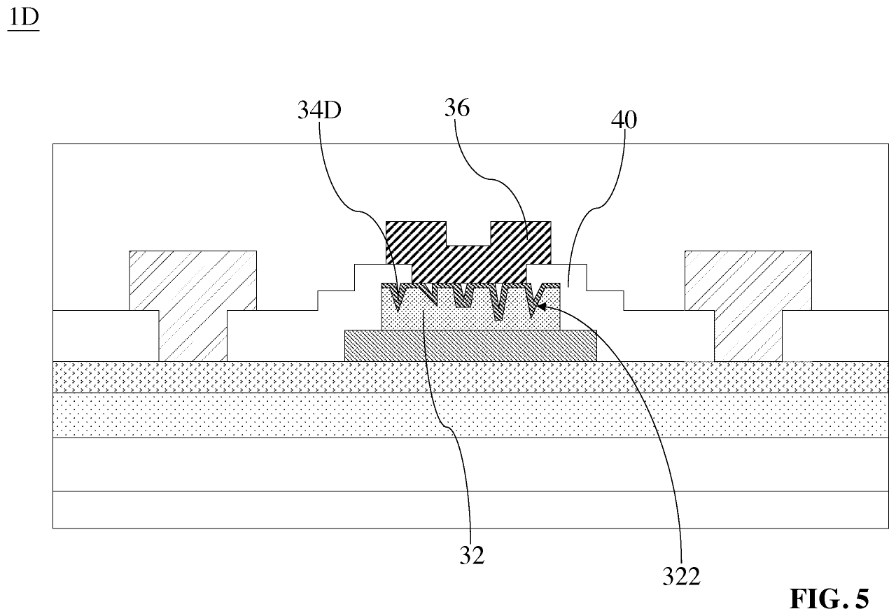

FIG. 5 is a vertical cross-sectional view of a nitride-based semiconductor device ID according to some embodiments of the present disclosure. The nitride-based semiconductor device ID is similar to the semiconductor device IA as described and illustrated with reference to FIG. 1, except that the conductive layer 34 of the semiconductor device 1A is replaced by a conductive layer 34D.

The recesses 322 of the conductive layer 32 are partially filled by the conductive layer 34D. The conductive layer 34D is a continuous layer covering the conductive layer 32. The conductive layer 34D is conformal with the profile constructed by the recesses 322 of the conductive layer 32. Therefore, the conductive layer 32 is separated from the gate electrode 36 by the conductive layer 34D. Since the gate electrode 36 is electrically coupled to the conductive layer 32 through the conductive layer 34D, the resistance between the gate electrode 36 and the conductive layer 32 can be improved at a condition that the conductive layer 34 is thin enough to comply with the design requirement.

The embodiments were chosen and described in order to best explain the principles of the disclosure and its practical application, thereby enabling others skilled in the art to understand the disclosure for various embodiments and with various modifications that are suited to the particular use contemplated.

As used herein and not otherwise defined, the terms “substantially,” “substantial,” “approximately” and “about” are used to describe and account for small variations. When used in conjunction with an event or circumstance, the terms can encompass instances in which the event or circumstance occurs precisely as well as instances in which the event or circumstance occurs to a close approximation. For example, when used in conjunction with a numerical value, the terms can encompass a range of variation of less than or equal to ±10% of that numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. The term “substantially coplanar” can refer to two surfaces within micrometers of lying along a same plane, such as within 40 μm, within 30 μm, within 20 μm, within 10 μm, or within 1 μm of lying along the same plane.

As used herein, the singular terms “a,” “an,” and “the” may include plural referents unless the context clearly dictates otherwise. In the description of some embodiments, a component provided “on” or “over” another component can encompass cases where the former component is directly on (e.g., in physical contact with) the latter component, as well as cases where one or more intervening components are located between the former component and the latter component.

While the present disclosure has been described and illustrated with reference to specific embodiments thereof, these descriptions and illustrations are not limiting. It should be understood by those skilled in the art that various changes may be made and equivalents may be substituted without departing from the true spirit and scope of the present disclosure as defined by the appended claims. The illustrations may not necessarily be drawn to scale. There may be distinctions between the artistic renditions in the present disclosure and the actual apparatus due to manufacturing processes and tolerances. Further, it is understood that actual devices and layers may deviate from the rectangular layer depictions of the FIGS. and may include angles surfaces or edges, rounded corners, etc. due to manufacturing processes such as conformal deposition, etching, etc. There may be other embodiments of the present disclosure which are not specifically illustrated. The specification and the drawings are to be regarded as illustrative rather than restrictive. Modifications may be made to adapt a particular situation, material, composition of matter, method, or process to the objective, spirit and scope of the present disclosure. All such modifications are intended to be within the scope of the claims appended hereto. While the methods disclosed herein have been described with reference to particular operations performed in a particular order, it will be understood that these operations may be combined, sub-divided, or re-ordered to form an equivalent method without departing from the teachings of the present disclosure. Accordingly, unless specifically indicated herein, the order and grouping of the operations are not limitations.

1. A nitride-based semiconductor device, comprising:
a first nitride-based semiconductor layer;
a second nitride-based semiconductor layer disposed over the first nitride-based semiconductor layer and having a bandgap greater than a bandgap of the first nitride-based semiconductor layer;
a first conductive layer disposed over the second nitride-based semiconductor layer and having a top surface and a plurality of recesses at the top surface;
a second conductive layer at least filling into the recesses, wherein the first conductive layer comprises at least one first element excluded in the second conductive layer; and
a gate electrode disposed over the first conductive layer and the second conductive layer.

2. The nitride-based semiconductor device of claim 1, wherein the second conductive layer comprises at least one second element, and the second element diffuses into the first conductive layer from the second conductive layer.

3. The nitride-based semiconductor device of claim 2, wherein the second element is aluminum and is different than the first element.

4. The nitride-based semiconductor device of claim 1, wherein the first element is titanium.

5. The nitride-based semiconductor device of claim 1, wherein the recesses of the first conductive layer have different depths.

6. The nitride-based semiconductor device of claim 1, wherein the gate electrode makes contact with the second conductive layer.

7. The nitride-based semiconductor device of claim 1, wherein the first conductive layer is separated from the gate electrode by the second conductive layer.

8. The nitride-based semiconductor device of claim 1, wherein the gate electrode makes contact with the first conductive layer.

9. The nitride-based semiconductor device of claim 1, wherein the second conductive layer is within a thickness of the first conductive layer, and the gate electrode is free from contact with the second conductive layer.

10. The nitride-based semiconductor device of claim 9, wherein the gate electrode makes contact with the first conductive layer.

11. (canceled)

12. The nitride-based semiconductor device of claim 1, further comprising:
a dielectric layer disposed over the second nitride-based semiconductor layer and covering the first conductive layer and the second conductive layer.

13. The nitride-based semiconductor device of claim 12, wherein the dielectric layer extends to the recesses to fill up the recesses.

14. The nitride-based semiconductor device of claim 1, further comprising:
a doped nitride-based semiconductor layer disposed between the second nitride-based semiconductor layer and the first conductive layer, wherein the doped nitride-based semiconductor layer is wider than the first conductive layer.

15. The nitride-based semiconductor device of claim 1, wherein the first conductive layer is a titanium nitrate layer and the second conductive layer is an aluminum layer.

16. A manufacturing method of a nitride-based semiconductor device, comprising:
forming a first nitride-based semiconductor layer;
forming a second nitride-based semiconductor layer on the first nitride-based semiconductor layer;
forming a first conductive layer over the second nitride-based semiconductor layer;
forming a second conductive layer to fill recesses of the first conductive layer; and
forming a gate electrode over the first and second conductive layer.

17. The manufacturing method of claim 16, further comprising:
cleaning a top surface of the first conductive layer by using a solution of hydrogen fluoride to remove oxygen prior to forming the second conductive layer.

18. The manufacturing method of claim 16, further comprising:
performing an annealing process after forming the second conductive layer such that at least one group III element diffuses into the first conductive layer.

19. The manufacturing method of claim 18, wherein the group III element is aluminum.

20. The manufacturing method of claim 16, wherein the second conductive layer is formed by deposition.

21. A nitride-based semiconductor device, comprising:
a first nitride-based semiconductor layer;
a second nitride-based semiconductor layer disposed over the first nitride-based semiconductor layer and having a bandgap greater than a bandgap of the first nitride-based semiconductor layer;
a first conductive layer disposed over the second nitride-based semiconductor layer and having a top surface and a plurality of recesses at the top surface; and
a second conductive layer at least filling into the recesses, wherein the second conductive layer comprises aluminum which diffuses into the first conductive layer.

22.-25. (canceled)
